(19) United States
(12) Patent Application Publication
(10) Pub. No.: US 2026/0352119 A1
(43) Pub. Date: Nov. 5, 2026

(54) SYSTEMS AND METHODS FOR AN INTERLOCKING FEATURE ON A POWER MODULE

(71) Applicant: BorgWarner US Technologies LLC, Wilmington, DE (US)

(72) Inventor: Edward CHOI, Lake Orion, MI (US)

(73) Assignee: BorgWarner US Technologies LLC, Wilmington, DE (US)

(21) Appl. No.: 19/742,400

(22) Filed: Jul. 15, 2026

Related U.S. Application Data
(63) Continuation of application No. 19/193,058, filed on Apr. 29, 2025.
Application No. 19/193,058 is a continuation of application No. 18/159,449, filed on Jan. 25, 2023, now Pat. No. 12,316,257.
(60) Provisional application No. 63/377,486, filed on Sep. 28, 2022.
(60) Provisional application No. 63/377,501, filed on Sep. 28, 2022.
(60) Provisional application No. 63/377,512, filed on Sep. 28, 2022.
(60) Provisional application No. 63/378,601, filed on Oct. 6, 2022.

(51) Int. Cl. H02M 7/5387; B60L 3/00; B60L 15/00; B60L 15/08; B60L 15/20; B60L 50/40; B60L 50/51; B60L 50/60; B60L 50/64; B60L 53/20; B60L 53/22; B60L 53/62; B60R 16/02; G01R 15/20; G06F 1/08; G06F 13/40; H02J 7/00; H02M 1/00; H02M 1/08; H02M 1/084; H02M 1/088; H02M 1/12; H02M 1/32; H02M 1/42; H02M 1/44; H02M 3/335; H02M 7/00; H02M 7/537; H02M 7/5395; H02P 27/06; H02P 27/08; H02P 29/024; H02P 29/68; H03K 19/20; H05K 1/14; H05K 1/181; H05K 1/182; H05K 5/02; H05K 7/20; H10D 64/01; H10W 40/00; H10W 40/20; H10W 40/22; H10W 40/25; H10W 40/43; H10W 40/47; H10W 40/60; H10W 70/40; H10W 70/60; H10W 70/685; H10W 70/692; H10W 72/00; H10W 72/30; H10W 90/00

(52) U.S. Cl. CPC H02M 7/5387; B60L 3/003; B60L 15/007; B60L 15/08; B60L 50/40; B60L 50/51; B60L 50/60; B60L 50/64; B60L 53/20; B60L 53/22; B60L 53/62; B60R 16/02; G01R 15/20; G06F 1/08; G06F 13/4004; H02J 7/855; H02M 1/0054; H02M 1/08; H02M 1/084; H02M 1/088; H02M 1/123; H02M 1/32; H02M 1/322; H02M 1/327; H02M 1/4258; H02M 1/44; H02M 7/003; H02M 7/537; H02M 7/53871; H02M 7/53875; H02M 7/5395; H02P 27/06; H02P 27/08; H02P 27/085; H02P 29/024; H02P 29/027; H02P 29/68; H05K 1/145; H05K 1/181; H05K 1/182; H05K 5/0247; H05K 7/20154; H05K 7/2039; H05K 7/2049; H05K 7/20854; H05K 7/209; H05K 7/20927; H10D 64/018; H10W 40/037; H10W 40/22; H10W 40/226; H10W 40/255; H10W 40/43; H10W 40/47; H10W 40/611; H10W 70/481; H10W 70/611; H10W 70/685; H10W 70/692; H10W 90/00; B60L 15/20; B60L 2210/30; B60L 2210/40; B60L 2210/42; B60L 2210/44; B60L 2240/36; G06F 2213/40; H02J 2207/20; H02M 1/0009; H02M 3/33523; H02P 2207/05; H03K 19/20; H05K 2201/042; H05K 2201/10166; H10W 40/235; H10W 40/60; H10W 72/07354; H10W 72/347; H10W 90/734; H10W 90/736

(57) ABSTRACT

A system includes a power module, wherein the power module includes an interlocking feature on a first surface of the power module; and at least one heat sink, wherein the surface of the at least one heat sink includes a layer of thermal interface material.

### CROSS-REFERENCE TO RELATED APPLICATION(S)

This application claims the benefit of priority to U.S. patent application Ser. No. 19/193,058, filed Apr. 29, 2025; which claims priority to U.S. patent application Ser. No. 18/159,449, filed Jan. 25, 2023; which claims priority to U.S. Provisional Patent Application No. 63/377,486, filed Sep. 28, 2022, U.S. Provisional Patent Application No. 63/377,501, filed Sep. 28, 2022, U.S. Provisional Patent Application No. 63/377,512, filed Sep. 28, 2022, and U.S. Provisional Patent Application No. 63/378,601, filed Oct. 6, 2022, the entireties of which are incorporated by reference herein.

### TECHNICAL FIELD

Various embodiments of the present disclosure relate generally to power modules, and more specifically, to systems and methods for providing Bond-Line-Thickness (BLT) control and an interlocking feature on a power module to, e.g., facilitate aligning the power module with one or more heat sinks during an assembly process.

### INTRODUCTION

The power module is one of the key components in a traction inverter for controlling performance and/or efficiency of a driving system. A critical aspect for performance and reliability stems from the correct Bond-Line-Thickness Control of TIM (Thermal-Interface-Material) and from the correct placement of the power module on the heat sink in a manner that creates a strong bonding integrity between the power module and heat sink.

### SUMMARY OF THE DISCLOSURE

In some aspects, the techniques described herein relate to a system including: a power module, wherein the power module includes an interlocking feature on a first surface of the power module; and at least one heat sink, wherein the surface of the at least one heat sink includes a layer of thermal interface material.

In some aspects, the techniques described herein relate to a system, wherein the power module includes the first interlocking feature on a second surface of the power module, wherein the second surface is separated from the first surface by a width of the power module.

In some aspects, the techniques described herein relate to a system, wherein the interlocking feature is a protruding interlocking feature.

In some aspects, the techniques described herein relate to a system, wherein the surface of the at least one heat sink is a flat surface.

In some aspects, the techniques described herein relate to a system, wherein the layer of thermal interface material includes thermal tapes, gels, thermal epoxies, solders, greases, gap-filled pads, and phase change materials.

In some aspects, the techniques described herein relate to a system, wherein the first surface and second surface include an epoxy mold compound or a copper layer.

In some aspects, the techniques described herein relate to a system, wherein the first interlocking feature on the first surface or second surface mates with the surface of the at least one heat sink to form a gap between the first surface or second surface of the power module and the surface of the at least one heat sink.

In some aspects, the techniques described herein relate to a system, wherein the gap between the first surface or second surface of the power module and the surface of the at least one heat sink is filled with thermal interface material.

In some aspects, the techniques described herein relate to a system, wherein the thermal interface material extends across an area of the at least one heat sink where the first interlocking feature on the power module does not mate with the surface of the at least one heat sink.

In some aspects, the techniques described herein relate to a system, wherein the at least one heat sink includes an inlet port or an outlet port.

In some aspects, the techniques described herein relate to a system including: a power module, wherein the power module includes a first interlocking feature on a first surface of the power module; and at least one heat sink, wherein the at least one heat sink includes a second interlocking feature on a surface of the at least one heat sink, wherein the first interlocking feature includes a height greater than a depth of the second interlocking feature, and wherein the surface of the at least one heat sink includes a layer of thermal interface material.

In some aspects, the techniques described herein relate to a system, wherein the power module includes the first interlocking feature on a second surface of the power module, wherein the second surface is separated from the first surface by a width of the power module.

In some aspects, the techniques described herein relate to a system, wherein the first interlocking feature is a protruding interlocking feature.

In some aspects, the techniques described herein relate to a system, wherein the second interlocking feature is a recessed interlocking feature.

In some aspects, the techniques described herein relate to a system, wherein the recessed interlocking feature is a blind cavity.

In some aspects, the techniques described herein relate to a system, wherein the first interlocking feature on the first surface or second surface mates with the second interlocking feature on the surface of the at least one heat sink to form a gap between the first surface or second surface of the power module and the surface of the at least one heat sink.

In some aspects, the techniques described herein relate to a system claim 16, wherein the gap between the first surface or second surface of the power module and the surface of the at least one heat sink is filled with thermal interface material.

In some aspects, the techniques described herein relate to a system, wherein the thermal interface material extends across an area of the surface of the at least one heat sink where the first interlocking feature on the power module does not mate with the second interlocking feature on the at least one heat sink.

In some aspects, the techniques described herein relate to a system, wherein the at least one heat sink includes an inlet port or an outlet port.

In some aspects, the techniques described herein relate to a system, wherein the first surface and second surface include an epoxy mold compound or a copper layer.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a vehicle including a traction inverter, according to one or more embodiments.

FIG. 2A and FIG. 2B depict a side view of an exemplary system of interlocking features on a power module and heat sinks, according to embodiments of the present disclosure.

FIG. 3A and FIG. 3B depict another embodiment of the exemplary system of interlocking features on a power module and heat sinks.

FIG. 4A and FIG. 4B depict another embodiment of the exemplary system of interlocking features on a power module and heat sinks.

FIG. 5A and FIG. 5B depict another embodiment of the exemplary system of interlocking features on a power module and heat sinks.

FIG. 6 depicts an exemplary method for aligning interlocking features on a heat sink to interlocking features on a power module.

### DETAILED DESCRIPTION OF EMBODIMENTS

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value. In this disclosure, unless stated otherwise, any numeric value may include a possible variation of ±10% in the stated value.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. For example, in the context of the disclosure, the power module may be described as a device, but may refer to any device for controlling the flow of power in an electrical circuit. For example, a power module may be a metal-oxide-semiconductor field-effect transistor (MOSFETs), bipolar junction transistor (BJTs), insulated-gate bipolar transistor (IGBTs), or relays, for example, or any combination thereof, but are not limited thereto.

An interlocking feature, as described herein, on a power module and/or heat sink may eliminate the tools required, during packaging assembly, for ensuring the correct placement of a power module on a heat sink. In addition, the interlocking feature may provide for an increase in the strength of bonding integrity between a power module and a heat sink. The increase in strength provided by the interlocking feature may reduce failure or cracking on a power module by creating strong interlocking bonding and tight control of bond line thickness.

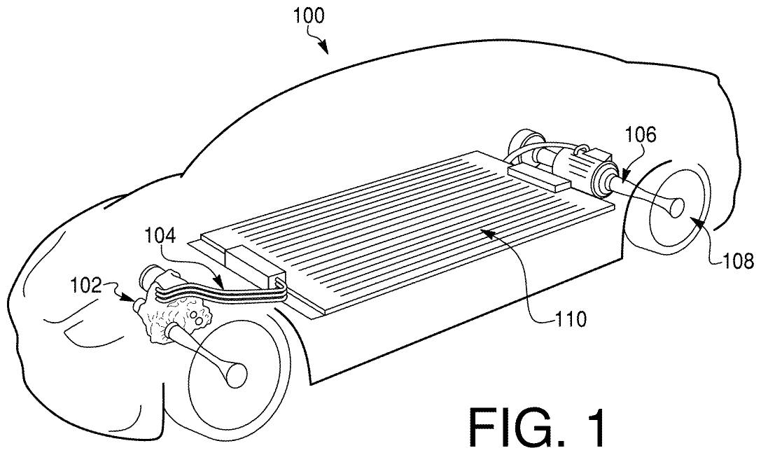

Turning now to FIG. 1, there is depicted an exemplary system infrastructure for a vehicle including traction inverter 102, according to one or more embodiments of the present disclosure. Electric vehicle 100 may include traction inverter 102, drive motor 106, battery 110, and connectors 104 connecting the inverter 102 and battery 110. Traction inverter 102 may include components to receive electrical power from an external source and output electrical power to charge battery 110 of electric vehicle 100. Traction inverter 102, through the use of a power module, may convert DC power from battery 110 in electric vehicle 100 to AC power, to power motor 106 and wheels 108 of electric vehicle 100, for example, but the embodiments are not limited thereto. The power module may be bidirectional, and may convert DC power to AC power, or convert AC power to DC power, such as during regenerative braking, for example. Traction inverter 102 may be a three-phase inverter, a single-phase inverter, or a multi-phase inverter.

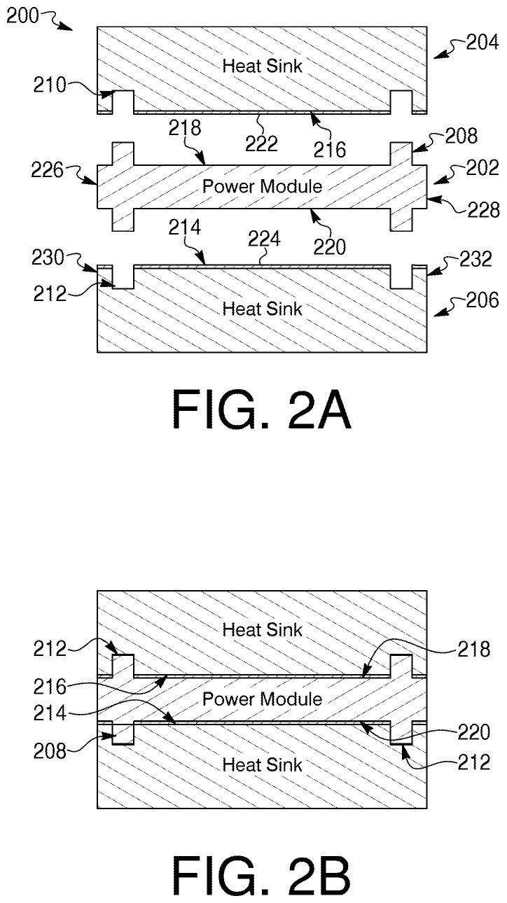

FIGS. 2A and 2B depict a side view of system 200, which may include power module 202, first heat sink 204, second heat sink 206, protruding interlocking features 208, recessed interlocking features 210 and 212, and thermal interface materials 222 and 224. System 200 may include power module 202 where first heat sink 204 may be located above first surface 218 (e.g., a top surface 218) of power module 202 and second heat sink 206 may be located beneath second surface 220 (e.g., a bottom surface 220) of power module 202. The power module 202 may include a plurality of protruding interlocking features 208. Protruding interlocking features 208 may include any suitable shape, geometry and configuration. For example, in some embodiments, protruding interlocking features 208 may actually be replaced with recesses configured to receive corresponding mating protrusions on heat sinks 204, 206. As shown in FIG. 2A, however, in one embodiment, protruding interlocking features 208 include a plurality of protrusions on top surface 218 where the protruding interlocking features 208 include of extensions of top surface 218. Power module 202 may also include a plurality of protruding interlocking features 208 on bottom surface 220 of power module 202 where protruding interlocking features 208 include of extensions of bottom surface 220.

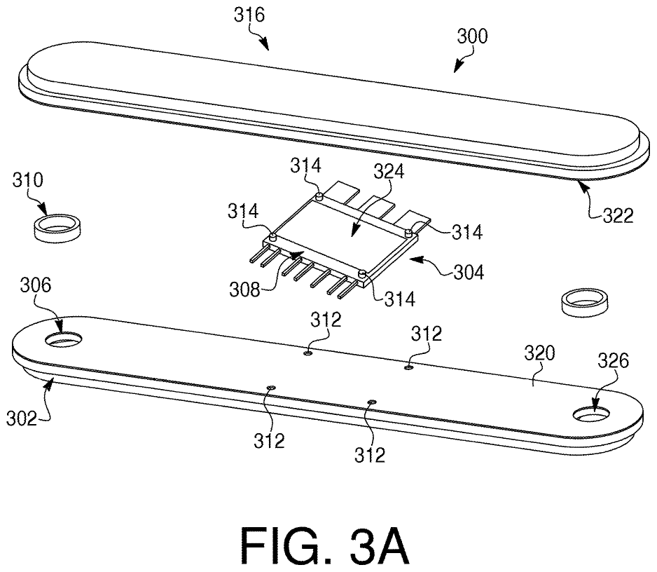

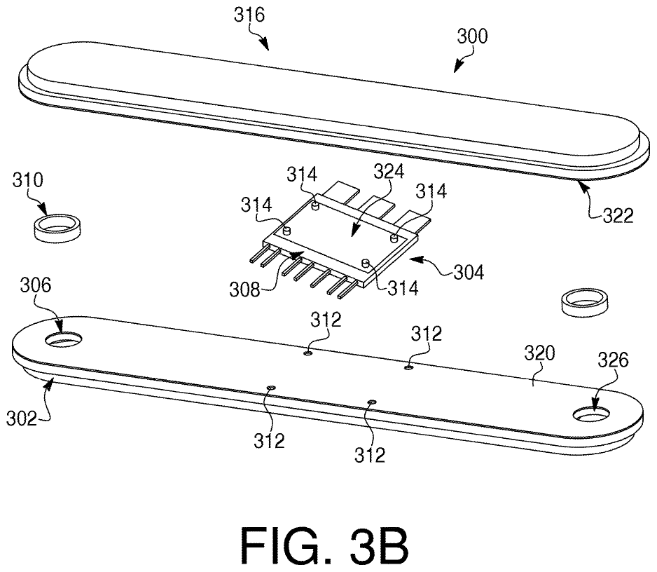

The protruding interlocking features 208 may include any suitable size, shape, or configuration. Moreover, though FIG. 2A depicts only two protruding interlocking features 208 on each of top surface 218 and bottom surface 220, those of ordinary skill in the art will understand that any suitable number of protruding interlocking features 208 are within the scope of the embodiments described herein. Indeed, as shown in FIG. 3A, alternative embodiments may include, e.g., four protruding interlocking features, as described in detail below. Still further, the number, size, or configuration of the protruding interlocking features 208 on top surface 218 may be the same as, or differ in one more aspects from, the protruding interlocking features 208 on bottom surface 220. Furthermore, one or more of the protruding interlocking features 208 may include any suitable material known in the art, including, but not limited to, copper, aluminum, or an alloy of copper and aluminum. Each of the protruding interlocking features 208 may be made of the same material composition, or one or more interlocking features 208 may include a material composition that differs from the material composition other protruding interlocking features 208.

In another implementation, only one side of power module 202 may include a plurality of protruding interlocking features 208. For instance, the top surface 218 of the power module may comprise of a plurality of protruding interlocking features 208 but bottom surface 220 of power module 202 may include a flat surface.

The plurality of protruding interlocking features 208 may all be located at an equal distance from the edges of power module 202. For example, one of the plurality of protruding interlocking features 208 may be located, e.g., approximately 2 mm from first edge 226 of power module and one of the other plurality of protruding interlocking features 208 may be located, e.g., approximately 2 mm from a second edge 228 of power module 202. In another implementation, the location of protruding interlocking features 208 from first edge 226 and second edge 228 of the power module 202 may differ in comparison to each other. For instance, one of the plurality of protruding interlocking features 208 may be located, e.g., approximately 3 mm from first edge 226 of power module 202 while one of the other protruding interlocking features 208 may be located, e.g., approximately 5 mm from second edge 228 of power module 202.

Power module 202 may include, e.g., an approximately 800-Volt Silicon Carbide Inverter (e.g., for electrified vehicles), although other suitable structures and uses also are contemplated. Power module 202 may include one or more silicon carbide (SiC)-based power modules that deliver relatively high power densities and efficiencies needed to extend battery range and performance. Power module 202 may contain circuitry and components configured to convert direct current (DC) from the electric vehicle battery to alternating current (AC) current, which can be utilized within the electric motor that drives the propulsion system. Power module 202 may be installed on one or more power board assemblies. Power module 202 may include a combination of transistors, diodes, metal oxide semiconductor field effect transistors (MOSFETs), insulated-gate bipolar transistors (IGBTs), and silicon-controlled rectifiers (SCRs). Power module 202 may include a combination of transistors configured to both a half-bridge and H-bridge configuration, which may allow for the switch ability of the direction of the current through a motor from a single voltage power supply. Additionally, Power module 202 may also include up to six transistors for inverting applications such as switching direct current electricity into alternating current.

First heat sink 204 may include a plurality of recessed interlocking features 210 on surface 216, where the recessed interlocking features 210 include a blind cavity in surface 216. Second heat sink 206 may also include a plurality of recessed interlocking features 212 on surface 214, where the recessed interlocking features include a blind cavity in surface 214.

Recessed interlocking features 210 and 212 may include any suitable size, shape, or configuration. Moreover, though FIG. 2A depicts only two recessed interlocking features 210 and 212 on each of surface 216 of first heat sink 204 and surface 214 of second heat sink 206, those of ordinary skill in the art will understand that any suitable number of recessed interlocking features 210 and 212 are within the scope of the embodiments described herein. Indeed, as shown in FIG. 3A, alternative embodiments may include, e.g., four recessed interlocking features, as described in detail below. Still further, the number, size, or configuration of the recessed interlocking features 210 on surface 216 may be the same as, or differ in one more aspects from, the recessed interlocking features 212 on surface 214.

The plurality of recessed interlocking features 210 and 212 may all be located at an equal distance from the edges of either first heat sink 204 or second heat sink 206. For example, one of the plurality of recessed interlocking features 210 may be located, e.g., approximately 2 mm from a first edge 230 of first heat sink 204 and one of the other plurality of recessed interlocking features 210 may be located, e.g., approximately 2 mm from a second edge 232 of first heat sink 204. In another implementation, the location of recessed interlocking features 210 and 212 from the edges of either first heat sink 204 and second heat sink 206 may differ between each other. For instance, one of the plurality of recessed interlocking features 210 may be, e.g., approximately 3 mm from first edge 230 of first heat sink 204 while one or more of the other plurality of recessed interlocking features 210 may be, e.g., approximately 5 mm from second edge 232 of heat sink 204.

The recessed interlocking features 210 and 212 and protruding interlocking features 208, when engaged, may produce a force that more uniformly spreads the TIM layer (discussed in greater detail below) on first and second heat sinks 204 and 206 which in turn may reduce the bond line thickness. In some examples, the entirety of the applied TIM layer may be within 15%, 10%, 5%, 3%, 2%, 1% or less of a median thickness. Moreover, the entirety of the outer surfaces of all power modules (except for exposed electrical connections) may be covered with TIM. The reduction in bond line thickness may relieve pressure on power module 202, which may reduce the risk of cracks and failure of the power module structure.

Surface 216 of first heat sink 204 and surface 216 of second heat sink 206 may include a layer of thermal interface material (TIM) 222 and 224, respectively, to further aid thermal conduction between first heat sink 204 and power module 202 as well as between second heat sink 206 and power module 202. TIM layers 222 and 224 may include any suitable thermal tapes, gels, thermal epoxies, solders, greases, gap-filled pads, phase change materials, or combinations thereof.

TIM layers 222 and 224 on either surface 214 or 216 may include TIM extending across a substantial entirety, or across only a portion, of either surface 214 and 216. Additionally, TIM layers 222 and 224 may include TIM across a portion of surface 214 and 216 between recessed interlocked features 210 and 212. The amount of TIM extending across surface 214 may be the same as, or differ in one more aspects from, the amount of TIM extending across surface 216. Furthermore, TIM layers 222 and 224 may include any suitable material known in the art, including, but not limited to, silicone elastomer, fiberglass, or combination thereof. Surface 214 may include TIM layer 222 which may be made of the same material composition as TIM layer 224 included on surface 216, or TIM layer 222 may include a material composition that differs from the material composition of TIM layer 224.

TIM layers 222 and 224 may be uniformly composed of the same material. In another implementation, TIM layers 222 and 224 be a composite of different materials. For example, TIM layers 222 and 224 may include a combination of a gel and a grease. In another implementation, for example, TIM layers 222 and 224 disposed in the blind cavity of recessed interlocking features 210 and 212 may be composed of a different material from the TIM layers 222 and 224 included on surfaces 214 and 216.

First heat sink 204 and second heat sink 206 may provide a thermal heat dissipation for power module 202. Heat sinks 204 and 206 may include multiple components. The material of heat sink 204 and 206 may be selected based on the required thermal performance needed to draw heat away from power module 202. For example, heat sinks 204 and 206 may be include an aluminum alloy having a high thermal conductivity while being mechanically soft. In another embodiment, heat sinks 204 and 206 may be include copper. In some embodiments, heat sinks 204 and 206 may be similar to a radiator used in an internal combustion engine and may include a circulating fluid or gas therein. Heat sinks 204 and 206 may be in an extruded, folded fin, bonded fin, active fan, stamping, or cross-cut configuration.

As shown in FIG. 2B, the plurality of protruding interlocking features 208 on top surface 218 of power module 202 may be mated with the plurality of recessed interlocking features 210 of first heat sink 204. Additionally, the plurality of protruding interlocking features 208 on bottom surface 220 of power module 202 may be mated with the plurality of recessed interlocking features 212 of second heat sink 206. The plurality of recessed interlocking features 210 and 212 may be wider than the plurality of protruding interlocking features 208 of power module 202 such that a substantial entirety of protruding interlocking features 208 are received therein. A lubricating material may be included on top of TIM layers 222 and 224 in order to facilitate mating of protruding interlocking features 208 with recessed interlocking features 210 and 212. Top surface 218 and bottom surface 220 of the power module 202 may include an adhesive material (not shown) to keep heat sinks 204 and 206 mated with power module 202 when large amounts of heat is generated by power module 202.

FIG. 3A and FIG. 3B depict another embodiment system 300. In the embodiment of system 300, protruding interlocking features 314 on power module 304 may be located on an epoxy mold compound 308 (as shown in FIG. 3A) or a copper layer 324 (as shown in FIG. 3B). Protruding interlocking features 314 may be located on any area of the epoxy mold compound 308 or copper layer 324 as long as the protruding interlocking features 314 align with corresponding recessed interlocking features 312 located on heat sinks 302 and 316. In both FIGS. 3A and 3B, the TIM layers 322 on both heat sinks 302 and 316 may include TIM extending across a substantial entirety or across only a portion of the surfaces of heat sinks 302 and 316. In another embodiment, TIM may only be included in the area in which the power module 304 will mate with heatsinks 302 and 316.

Heat sinks 302 and 316 may include integral fluid conducting micro-channels used for liquid cooling. In particular, heat sinks 302 and 316 may comprise one or more inlet ports 306 for supplying liquid coolants within the respective heat sink and one or more outlet ports 326 for exhausting coolant that has passed through the fluid conducting micro-channels. Heat sinks 302 and 316 may also include a fluid seal 310 to fluidly seal the inlet port 306 and outlet port 326. The fluid conducting micro-channels coupled with TIM layers may allow for more efficient cooling of the power module.

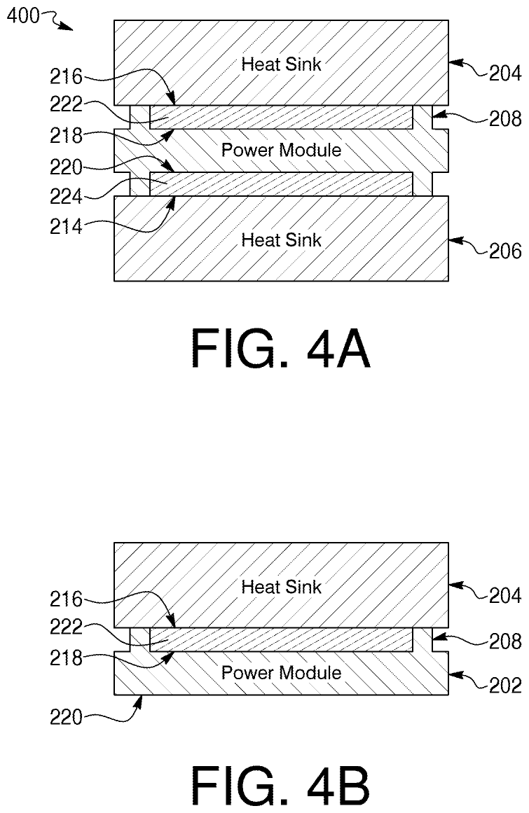

FIG. 4A and FIG. 4B depict another exemplary embodiment system 400 which is similar to the embodiment system 200 (as shown in FIGS. 2A and 2B). However, system 400 differs from system 200 in that surface 216 of first heat sink 204 and surface 214 of second heat sink 206 do not include a plurality of recessed interlocking features (as shown in FIG. 4A). Surface 216 of first heat sink 204 and surface 214 of second heat 206 may be a substantially, flat, or otherwise continuous surface.

The plurality of protruding interlocking features 208 on top surface 218 of power module 202 may be in contact with surface 216 of first heat sink 204 where a gap is formed between surface 216 and top surface 218. Additionally, the plurality of protruding interlocking features 208 on bottom surface 220 of power module 202 may be in contact with surface 214 of second heat sink 206 where a gap is formed between surface 214 and bottom surface 220. The gap formed between the heat sink 204 and 206 and power module 202 may be uniform. In another implementation, the height of the plurality of protruding interlocking features 208 on top surface 218 may differ than the height of the plurality of protruding interlocking on the bottom surface 220. Therefore, the height of the gap formed when the protruding interlocking features 208 on top surface 218 is in contact with surface 216 of first heat sink 204 may differ from the height of the gap formed when the protruding interlocking features 208 on bottom surface 220 is in contact with surface 214 of second heat sink 206.

TIM layers 222 and 224 on either surface 214 or 216 may include TIM extending across a substantial entirety, or across a portion of an area in which the power module does not mate with heat sinks 204 and 206. Moreover, the thickness of TIM layers 222 and 224 may fill the entire gap formed between the surfaces of the heat sink and power module. In another implementation, the amount of TIM filling the gap between top surface 218 and surface 216 of first heat sink 204 may be the same as, or differ in one or more aspects from, the amount of TIM filling the gap between bottom surface 220 and surface 214 of second heat sink 206.

In another embodiment, as shown in FIG. 4B, system 400 may include a power module 202 and a single heat sink 204 (or 206). The plurality of protruding interlocking features 208 may only be included on a single surface (top surface 218 or bottom surface 220) of power module 202 while the other surface (top surface 218 or bottom surface 220) may be a flat or otherwise free surface. The single heat sink 204 (or 206) may not include a plurality of recessed interlocking features 210 (or 212). Surface 218 (or 220) includes the plurality of protruding interlocking features 208 on power module 202 may be brought into proximity of or in contact with surface 216 (or 214) of the single heat sink 204 or 206 such that a gap is formed between surface 216 (or 214) of heat sink 204 or 206 and surface 218 (or 220) of power module 202. TIM layer 222 (or 224) may uniformly fill the gap between surface 216 (or 214) of heat sink 204 (or 206) and surface 218 (or 220) of power module 202. Furthermore, TIM layer 222 (or 224) on surface 216 (or 214) of the single heat sink 204 (or 206) may include TIM extending across an substantial entirety, or across a portion of an area in which the power module may not be in contact with the single heat sink 204 (or 206).

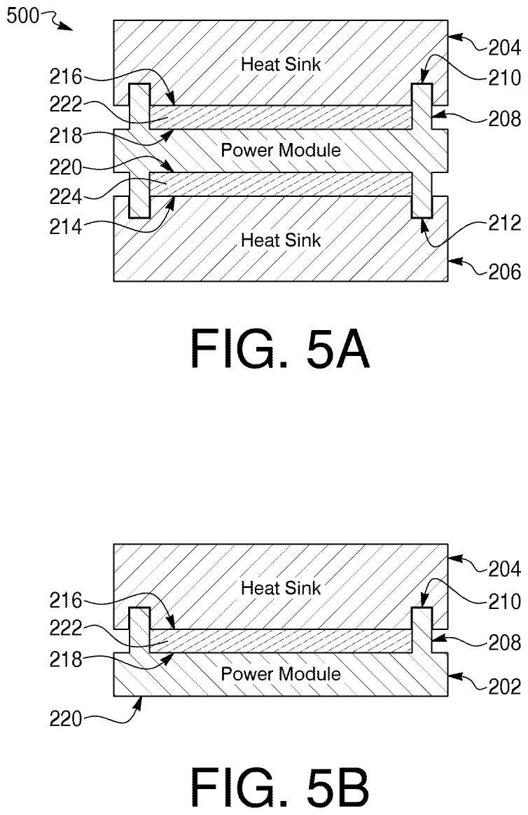

FIG. 5A and FIG. 5B depict another embodiment system 500 which is similar to embodiment system 200 (as shown in FIGS. 2A and 2B). However, system 500 differs from system 200, as shown in FIG. 5A, in that the height of the plurality of protruding interlocking features 208 on top surface 218 may be greater than the depth of the plurality of recessed interlocking features 210 on surface 216 of first heat sink 204. Additionally, the height of the plurality of protruding interlocking features 208 on bottom surface 220 of power module 202 may be greater than the depth of the plurality of recessed interlocking features 212 on surface 214 of second heat sink 206.

The plurality of protruding interlocking features 208 on top surface 218 of power module 202 may be mated with the plurality of recessed interlocking features 210 of first heat sink 204 such that a gap is formed between surface 216 and top surface 218. Additionally, the plurality of protruding interlocking features 208 on bottom surface 220 of power module 202 may be mated with the plurality of recessed interlocking features 212 of second heat sink 206 such that a gap is formed between surface 214 and bottom surface 220. The gap formed between the heat sink 204 and 206 and power module 202 may be uniform. In another implementation, the height of the plurality of protruding interlocking features 208 on the top surface 218 may differ than the height of the plurality of protruding interlocking on the bottom surface 220. Therefore, the height of the gap formed when the protruding interlocking features 208 on top surface 218 are mated to the plurality of recessed interlocking features 210 of first heat sink 204 may differ from the height of the gap formed when the protruding interlocking features 208 on bottom surface 220 are mated to the plurality of recessed interlocking features 212 of second heat sink 206.

TIM layers 222 and 224 on either surface 214 or 216 may include TIM extending across a substantial entirety, or across a portion of an area in which power module 202 does not make contact with heat sinks 204 and 206. Moreover, the thickness of TIM layers 222 and 224 may fill the entire gap formed between the surface of the heat sink and power module. In another implementation, the amount of TIM filling the gap between top surface 218 and surface 216 of first heat sink 204 may be the same as, or differ in one or more aspects from, the amount of TIM filling the gap between bottom surface 220 and surface 214 of second heat sink 206.

In another embodiment, as shown in FIG. 5B, system 500 may include a power module 202 and a single heat sink 204 (or 206). The plurality of protruding interlocking features 208 may only be included on a single surface (top surface 218 or bottom surface 220) of power module 202 while the other surface (top surface 218 or bottom surface 220) may be a flat, free surface. The single heat sink 204 (or 206) may include a plurality of recessed interlocking features 210 (or 212) which may have a depth that is less than the height of the plurality of protruding interlocking features 208. The plurality of protruding interlocking features 208 on power module 202 may be received within a plurality of recessed interlocking features of heat sink 204 (or 206) such that a gap is formed between surface 216 (or 214) of heat sink 204 (or 206) and surface 218 (or 220) of power module 202. TIM layer 222 (or 224) may uniformly fill the gap between surface 216 (or 214) of heat sink 204 (or 206) and surface 218 (or 220) of power module 202. Furthermore, TIM layer 222 (or 224) on surface 216 (or 214) of heat sink 204 (or 206) may include TIM extending across a substantial entirety, or across a portion of an area in which the power module does not mate with the single heat sink 204 (or 206).

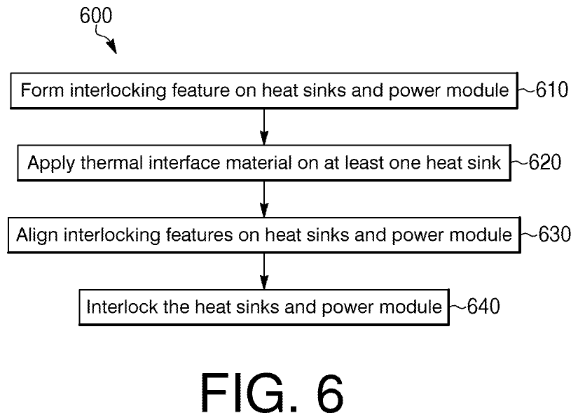

FIG. 6 depicts an exemplary method 600 for aligning a heat sink to a power module. As shown in FIG. 6, a method 600 may include, at step 610, forming one or more interlocking features on heat sinks 204, 206 and power module 202. For example, slabs of copper may be soldered to external surface of power module 202 to create protruding interlocking features 208. Correspondingly recessed interlocking features 210, 212 may be machined or laser drilled into surfaces 214, 216 of heat sinks 204, 206. Moreover, any suitable analyses, e.g., finite element analysis, may be performed to determine ideal locations for both protruding interlocking features 208 and recessed interlocking features 210, 212.

Once protruding interlocking features 208 and recessed interlocking features 210 and 212 have been formed on power module 202 and heat sinks 204, 206 respectively, thermal interface material 222, 224 may be applied to surfaces of heat sinks 204, 206 or surfaces 218, 220 of power module 202 at step 620. For example, solder paste, silver sinter paste, or a pump may be used to dispense the TIM material on to at least one heat sink 204, 206 or power module 202. In one example, the pump may be a piston pump which may create little to no friction during dispensing of the TIM. In other examples, the pump may be a screw pump for dispensing the TIM. The TIM may be dispensed or otherwise deposited onto heat sinks 204, 206 or power module 202 in any suitable pattern, including, but not limited to, such as a dot, serpentine, or spiral.

Once the TIM has been dispensed on heat sinks 204, 206, protruding interlocking features 208 may be aligned with recessed interlocking features 210 and 212. Subsequently, the protruding interlocking features 208 may be mated (e.g., inserted into) with recessed interlocking features 210, and 212, thereby aligning the one more heat sinks 204, 206 with power module 202 at step 630. Heat sinks 204, 206 and power module 202 may be aligned with one another with a deformable washer or a spring-action clamp. Heat sinks 204, 206 and power module 202 may be interlocked with one another at step 640.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A system comprising:
a power module including a protruding interlocking feature on a surface of the power module;
a heat sink including a recessed interlocking feature on a surface of the heat sink, wherein the protruding interlocking feature is received within the recessed interlocking feature; and
a layer of thermal interface material disposed between the surface of the power module and the surface of the heat sink,
wherein the protruding interlocking feature and the recessed interlocking feature are configured such that, when engaged, the layer of thermal interface material has a thickness variation of 15% or less of a median thickness across the layer.

2. The system of claim 1, further comprising:
a second heat sink, wherein the second heat sink is positioned adjacent to a second surface of the power module opposite the surface of the power module.

3. The system of claim 1, wherein the power module further includes a plurality of protruding interlocking features on both the surface and a second surface of the power module opposite the surface.

4. The system of claim 1, wherein the layer of thermal interface material is disposed in a pattern on the surface of the heat sink.

5. The system of claim 1, wherein the heat sink includes fluid conducting micro-channels, an inlet port for supplying liquid coolant to the micro-channels, and an outlet port for exhausting coolant from the micro-channels.

6. The system of claim 1, wherein the surface of the power module includes an epoxy mold compound, and wherein the protruding interlocking feature is located on the epoxy mold compound.

7. The system of claim 1, further comprising:
a lubricating material on top of the layer of thermal interface material to facilitate mating of the protruding interlocking feature with the recessed interlocking feature.

8. A system comprising:
a power module including a plurality of protruding interlocking features on a surface of the power module; and
a heat sink having a substantially flat and continuous surface facing the surface of the power module, wherein the substantially flat and continuous surface is free of recessed interlocking features,
wherein the protruding interlocking features contact the substantially flat and continuous surface of the heat sink to form a uniform gap between the surface of the power module and the substantially flat and continuous surface of the heat sink; and a layer of thermal interface material disposed within the uniform gap.

9. The system of claim 8, wherein the layer of thermal interface material fills an entirety of the uniform gap.

10. The system of claim 8, wherein the protruding interlocking features include extensions of the surface of the power module.

11. The system of claim 8, further comprising:
a second heat sink having a second substantially flat and continuous surface, wherein the power module includes a plurality of protruding interlocking features on a second surface of the power module opposite the surface, and wherein the protruding interlocking features on the second surface contact the second substantially flat and continuous surface.

12. The system of claim 8, further comprising:
an adhesive material on the surface of the power module to keep the heat sink mated with the power module.

13. The system of claim 8, wherein the heat sink includes an inlet port for supplying coolant and an outlet port for exhausting coolant.

14. The system of claim 8, wherein the heat sink includes a fluid seal to fluidly seal an inlet port and an outlet port of the heat sink.

15. A traction inverter for an electric vehicle, comprising:
a power module configured to convert DC power from a battery of the electric vehicle to AC power to drive a motor of the electric vehicle, wherein the power module includes a first interlocking feature on a surface of the power module;
a heat sink including a second interlocking feature on a surface of the heat sink, wherein the first interlocking feature mates with the second interlocking feature to align the power module with the heat sink; and
a layer of thermal interface material disposed between the power module and the heat sink.

16. The traction inverter of claim 15, wherein the layer of thermal interface material is disposed in a pattern on the surface of the heat sink.

17. The traction inverter of claim 15, further comprising:
a lubricating material on top of the layer of thermal interface material to facilitate mating of the first interlocking feature with the second interlocking feature.

18. The traction inverter of claim 15, wherein the first interlocking feature is a protruding interlocking feature, wherein the second interlocking feature is a recessed interlocking feature, and wherein the recessed interlocking feature is wider than the protruding interlocking feature such that a substantial entirety of the protruding interlocking feature is received within the recessed interlocking feature.

19. The traction inverter of claim 15, wherein the heat sink includes fluid conducting micro-channels, an inlet port for supplying liquid coolant to the micro-channels, and an outlet port for exhausting coolant from the micro-channels.

20. The traction inverter of claim 15, wherein the first interlocking feature is a protruding interlocking feature and the second interlocking feature is a recessed interlocking feature.
